(19) United States
(12) Patent Application Publication
(10) Pub. No.: US 2006/0049724 A1
(43) Pub. Date: Mar. 9, 2006

(54) Resonator element, resonator and electronic device

(75) Inventor: Makoto Eguchi, Suwa-shi (JP)

Correspondence Address: OLIFF & BERRIDGE, PLC, P.O. BOX 19928, ALEXANDRIA, VA, 22320, US

(73) Assignee: SEIKO EPSON CORPORATION, Tokyo (JP)

(21) Appl. No.: 11/206,112

(22) Filed: Aug. 18, 2005

(30) Foreign Application Priority Data
Aug. 19, 2004 (JP) 2004-239093

(51) Int. Cl. H01L 41/04; H01L 41/08

(52) U.S. Cl. 310/367

(57) ABSTRACT

A resonator element made of piezo-electric material having a thickness in a Z-direction includes a plurality of rod-like arms extending in a Y-direction, which is a rotational axis for the resonator element rotation; a plurality of rod-like beams extending in an X-direction, perpendicular to the direction in which the plurality of rod-like arms extend, and connecting to the plurality of rod-like arms in an XY-plane; an exciting electrode, located on a plane that opposes the XY-plane and opposes a YZ-plane of the plurality of rod-like arms, to excite the plurality of rod-like arms to perform a curvature movement on the XY-plane; and a detecting electrode, located on a plane that opposes the XY-plane of the beam, to detect a stress of the beam, which is generated by a Coriolis force yielded in the plurality of rod-like arms by the rotation of the resonator element corresponding to the Y-axis as the rotational axis.

This application claims the benefit of Japanese Patent Application No. 2004-239093, filed Aug. 19, 2004. The entire disclosure of the prior application is hereby incorporated by reference herein in its entirety.

### BACKGROUND

The exemplary embodiments relate to a resonator element, a resonator and an electronic device for gyro resonator.

In general, when a resonator element is formed for gyro resonator by using a piezo-electric material, a detecting electrode and exciting electrode are installed in the resonator element, making a resonator element perform flexural vibration, and detecting a stress caused by Corioli force with a detecting electrode when the resonator element is rotated. A related Japanese Patent Publication 7-55479 (see FIG. 1 to FIG. 3) discloses an H type resonator element having a thickness toward a Z-axis, in which a beam for a tuning fork is located extending the Y-direction, a tuning fork is placed at the XY plane and a rotational speed of the rotation on a Y-axis is detected. The structure of the electrode in the resonator element includes an exciting electrode formed on the XY plane opposing a exciting beam and a detecting electrode on the YZ plane which is the side of the detecting arm (a pick up arm.) The detecting electrode is split into two parts toward the thickness direction at the side of the detecting arm for detecting a stress generated in the detecting arm.

The above resonator element has the H-type configuration and an electrode formed by a photolithography with high precision. The detecting electrode at the side of the detecting arm, however, is not accurately formed due to the following reason: namely, the side of the detecting arm is outer etched and anisotropy corresponding to a crystal axis direction exists in a piezo-electric material, causing an etched surface not to be planarized. Further, in order to split the detecting electrode toward the thickness direction, light must be irradiated from an oblique direction, worsening exposure accuracy compared to a case when a plane is vertically open to the elements. Thus, it is difficult to form an electrode at the side of the detecting arm with high precision, lowering product efficiency. Further, there is a relationship between size accuracy of a detecting electrode and stress detection sensitivity, deteriorating this sensitivity when the size accuracy of a detecting electrode is bad. Therefore, the above problem causes detecting capability for a rotational speed to be lowered in a resonator element of a gyro resonator.

### SUMMARY

In order to address or overcome the above problem, the exemplary embodiments provide a resonator element, which is capable of detecting a rotational speed with high precision and high efficiency in production. Further, the exemplary embodiments provide a resonator detecting a rotational speed with high precision and an electronic device being provided with this resonator.

According to a first aspect of the exemplary embodiments, a resonator element made of a piezo-electric material having a thickness in a Z-direction, the resonator element including a plurality of rod-like arms extending in a Y direction, which is a rotational axis for the rotation of the resonator element; a plurality of rod-like beams extending in an X-direction, perpendicular to the direction in which the plurality of rod-like arms extend, and connecting to the arms in an XY-plane; an exciting electrode, located on a plane opposing the XY-plane and YZ plane, to excite the plurality of rod-like arms to perform a curvature movement on the XY-plane; and a detecting electrode, located on a plane opposing the XY-plane of the beam, to detect a stress of the beam, which is generated by a Coriolis force yielded in the plurality of rod-like arms by the rotation of the resonator element corresponding to a Y-axis, as the rotational axis.

According to this structure, the detecting electrode is easily formed on an even XY-plane, with high precision. Accordingly, the resonator element has high efficiency in production and high sensitivity in detecting a rotational speed.

A material of the piezo-electric material of the resonator element may be quartz. Alternatively, a material of the piezo-electric material of the resonator element may be gallium phosphate (Ga PO₄).

Accordingly, using a quartz or gallium phosphate as a piezo-electric material for the resonator element leads to high stabilized oscillation and to high precision in detecting the rotational speed.

Further, the resonator element may include at least a pair of detecting electrodes on one surface of the XY-plane of the beam, and at least a pair of detecting electrodes on another surface of the XY-plane of the beam.

Thus, installing at least the pair of detecting electrodes on the same surface, and both front and back sides of the beam, can detect acceleration, which is a disturbance for Y-rotation of the resonator element.

Further, the detecting electrode may be located between two arms of the beam.

This location of the detecting electrode between two arms in which a stress is greatly generated by a Corioli force can result in precisely detecting the stress and can therefore provide a resonator element with a high capability of detecting a rotational speed.

Further, the configuration of the resonator element, the exciting electrode and the detecting electrode may be formed by photolithography.

This formation of the configuration of the resonator element, the exciting electrode and the detecting electrode by photolithography can give a precious dimension of size and configuration of the electrodes and provide a resonator element with high capability of detecting a rotational speed.

Further, a resonator of the exemplary embodiments may include the above described resonator element.

Such a resonator having the above described resonator element has high efficiency in its production and high sensitivity of detecting a rotational speed.

Further, an electronic device of the exemplary embodiments may include the above described resonator element.

Such an electronic equipment having the above described resonated element has high sensitivity of detecting rotational speed and high performance.

### BRIEF DESCRIPTION OF THE DRAWINGS

The exemplary embodiments will be described with reference to the accompanying drawings, wherein like numbers refer to like elements, and wherein:

FIG. 1 is a perspective view of a configuration of a resonator element in a first exemplary embodiment;

FIG. 2 is a plan view of a electrode located on one surface of the resonator element in the first exemplary embodiment;

FIG. 3 is a plan view of a electrode located on a back surface of the resonator element in the first exemplary embodiment;

FIG. 4(a) is a perspective view of the operation of the resonator element in an driving mode in an exemplary embodiment;

FIG. 4(b) is a perspective view of the operation of the resonator element in a detecting mode in an exemplary embodiment;

FIGS. 5(a) to 5(c) are schematics of patterns of electric fields in an driving mode and detecting mode in the first exemplary embodiment, FIG. 5(a) is a cross section along the line A-A in FIG. 2 in a driving mode, FIG. 5(b) is a cross section along the line B-B in FIG. 2 in a driving mode, and FIG. 5(c) is a cross section along the lines C-C and D-D in a detecting mode shown in FIG. 2;

FIG. 6 is a perspective view showing a state of acceleration in the resonator element in an exemplary embodiment;

FIGS. 7(a) and 7(b) are schematics of patterns of electrical fields in a beam in a state of acceleration in the first exemplary embodiment, FIG. 7(a) is an across section along the line C-C in FIG. 2, and FIG. 7(b) is an across section along the line C-C in FIG. 2;

FIG. 8 is a plan view of a electrode located on one surface of the resonator element in a modification of the first exemplary embodiment;

FIG. 9 is a plan view of an electrode located on a back surface of the resonator element in a modification of the first exemplary embodiment;

FIG. 10 is a plan view of the resonator element in another modification of the first exemplary embodiment;

FIG. 11 is a cross section of the resonator element in a second exemplary embodiment; and

FIG. 12 shows a structure of an electronic device in a third exemplary embodiment.

### DETAILED DESCRIPTION OF EMBODIMENTS

Exemplary embodiments of the present invention will be described with reference to the accompanying drawings.

### First Exemplary Embodiment

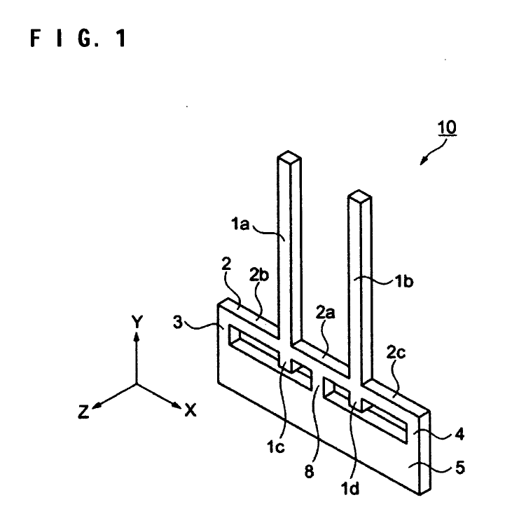

FIG. 1 is a perspective view of a resonator element in an exemplary embodiment. Firstly, the configuration of the resonator element is explained.

A resonator element 10 has an external configuration by using an approximate Z quartz plate, which is a piezo-electrode material, and photolithography. The resonator element 10 has two rod-like arms 1a and 1b, each with a predetermined length, which extend toward a Y-axis. These two rod-like arms 1a and 1b are coupled to a rod-like beam 2, which extends toward a direction perpendicular to the direction of the extending arms 1a and 1b. The ends of arms 1a and 1b include a lower end, 1c and 1d, respectively.

The beam 2 includes a detecting part of a beam 2a and connecting parts of a beam 2b and 2c, which are located outside of the arms 1a and 1b. The edge of the connecting part of a beam 2b of the arm 2 is coupled to a first connecting portion 3 and the edge of the connecting part of a beam 2c of the arm 2 is coupled to a second connecting portion 4. Further, the center portion of the detecting part of a beam 2a is coupled to a third connecting portion 8. The first connecting portion 3, the second connecting portion 4, and the third connecting portion 8 are coupled to a base 5. Each portions of the resonator element 10 has the same thickness toward the Z-direction (thickness direction.)

As the material for the resonator element 10, the piezo-electric material may be gallium phosphate (Ga PO₄).

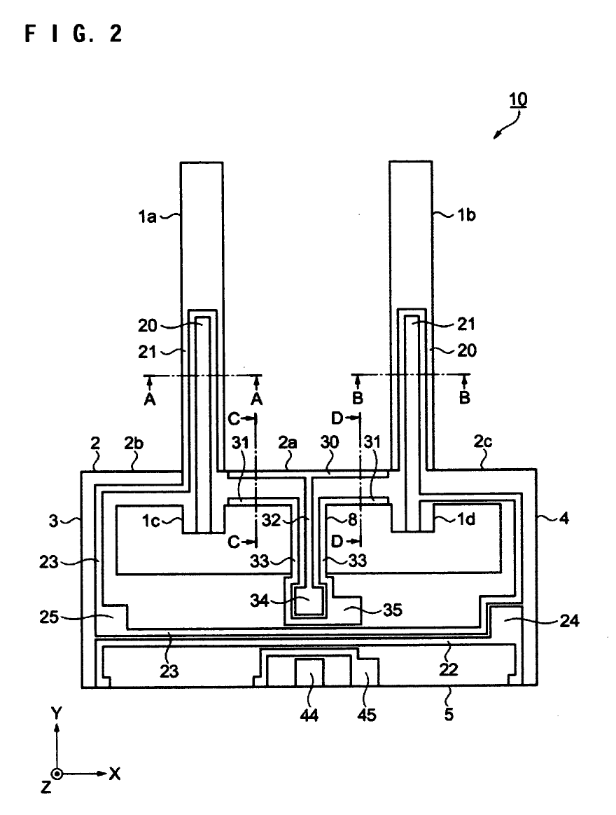

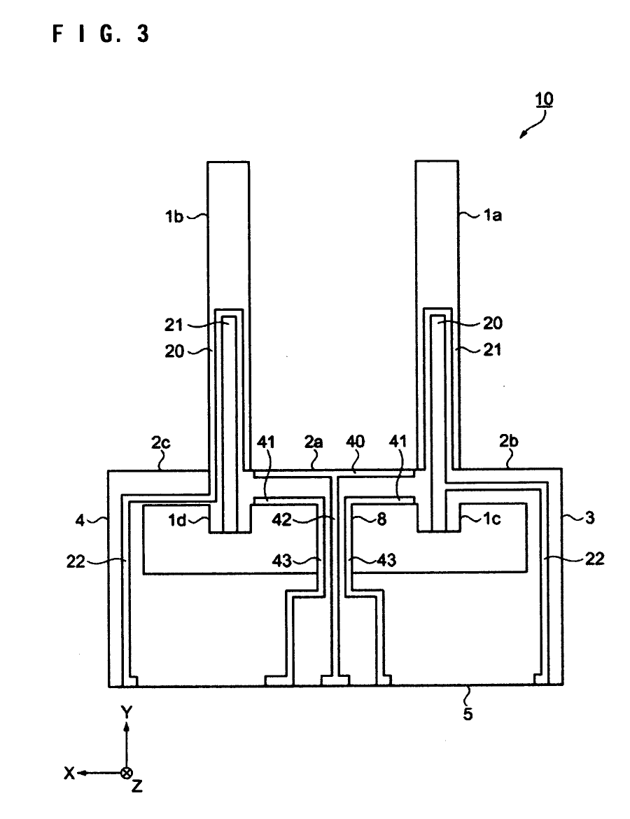

FIG. 2 is a plan view of an electrode located on one (front) surface of the resonator element 10 and FIG. 3 is a plan view of an electrode located on another (back) surface of the resonator element 10.

A first exciting electrode 20 is formed in the center of a XY plane of the arm 1a and a second exciting electrode 21 is formed from the end of the XY plane of the arm 1a toward a YZ plane.

The first exciting electrode 20 is coupled to the other first exciting electrode 20 located at the backside of the resonator element 10 via passing a XZ plane and the lower end 1c of the beam 1a. In the cross section of a dotted line A-A of the arm 1a, the first exciting electrode 20 is formed opposing the XY plane of the arm 1a, and the second exciting electrode 21 is formed opposing the YZ plane.

Further, the first exciting electrode 20 formed on the beam 1a in the backside of the resonator element 10 is coupled to a lead electrode 22, which passes the first connecting portion 3 to the end of the base 5. This passes from the end of the base 5 to the XZ plane and coupled to the exciting electrode pad 24 formed on the surface of the base 5. Furthermore, the exciting electrode pad 24 goes from a XZ plane to the backside via the end part of the base 5, and is coupled to the first exciting electrode 20, which is formed from the end of XY plane to the YZ plane.

The second exciting electrode 21 formed on the arm 1a goes through the lead electrode 23 and is coupled to the exciting electrode pad 25 formed on the base 5. Then, the exciting electrode pad 25 is coupled to the lead 23 and the second exciting electrode 21 formed in the center of the XY plane of the arm 1b. Further, the second exciting electrode 21 is coupled to the other second electrode 21 located at the backside of the resonator element 10 via passing the lower end of the beam 1d of the arm 1b. Hence, in the cross section of a dotted line B-B of the arm 1b, the second exciting electrode 21 is formed opposing the XY plane of the arm 1b and the first exciting electrode 20 is formed opposing the YZ plane.

Accordingly, the first electrode 20 is of a different polarity from that of the second electrode 21 forming a pair of electrodes.

Here, exciting electrodes formed from the end of the XY plane of each of the arms 1a and 1b to the YZ plane are located at least in the YZ plane and can excite the arms 1a and 1b to perform flexural vibration toward the X-axis in a driving mode described hereafter.

Further, a pair of the detecting electrodes 30 and 31 is formed in the XY plane on one surface (a front surface) of the resonator element 10. The first detecting electrode 30 is installed close to the ridge of the detecting part of a beam 2a and is coupled to the lead 32. The lead 32 goes through the third connecting portion 8 and is coupled to the detecting electrode pad 34 formed on the base 5. Further, the second detecting electrode 31 is installed close to the other ridge of the detecting part of a beam 2a and is coupled to the lead 33. The lead 33 goes through the third connecting portion 8 and is coupled to the detecting electrode pad 35 formed on the base 5. Accordingly, the pair of the detecting electrodes 30 and 31 can detect a stress generated in the detecting part of the beam 2a on the front surface.

Further, a pair of the detecting electrodes 40 and 41 is formed in the XY plane on the other surface (a back surface) of the resonator element 10. The third detecting electrode 40 is installed close to the ridge of the detecting part of the beam 2a and is coupled to the lead electrode 42. The lead electrode 42 goes through the third connecting portion 8 via the XZ surface from the end of the base 5, and is coupled to the detecting electrode pad 44 formed on the surface of the base 5. Further, the fourth detecting electrode 41 is installed close to the other ridge of the detecting part of the beam 2a and is coupled to the lead electrode 43. The lead electrode 43 goes through the third connecting portion 8 and is coupled to the detecting electrode pad 45 formed on the surface of the base 5 via the XZ surface from the end of the base 5. Accordingly, the pair of the detecting electrodes 40 and 41 can detect a stress generated in the detecting part of the beam 2a on the backside of the resonator element 10.

Here, exciting electrode pads 24 and 25 and detecting electrode pads 34, 35, 44 and 45 are coupled to the wiring by wire bonding or conductive adhesives.

These electrodes installed on the resonator element 10 are formed with high precision and made of Au.

Next, an driving mode and a detecting mode of the above resonator element are explained.

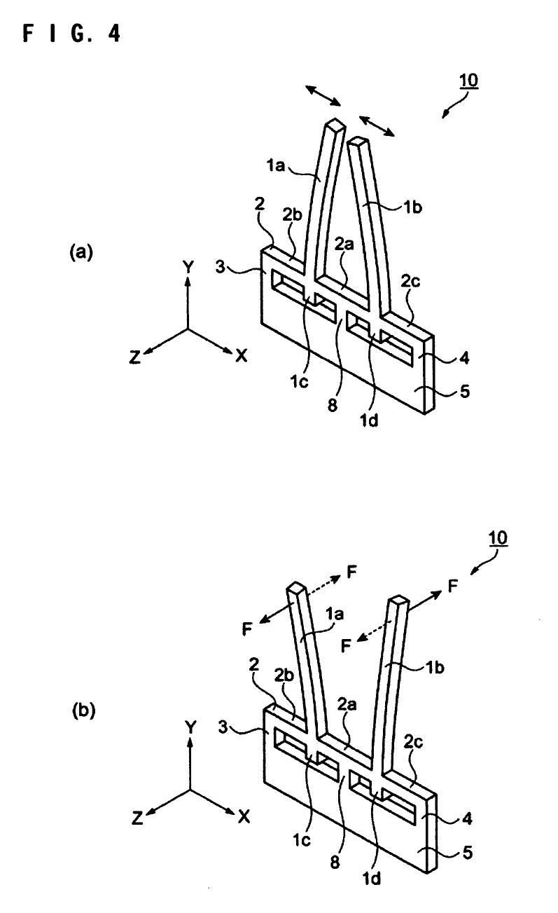

FIGS. 4(a) and 4(b) are perspective views showing resonator movement. FIG. 4(a) shows the movement in the driving mode and FIG. 4(b) shows the movement in the detecting mode.

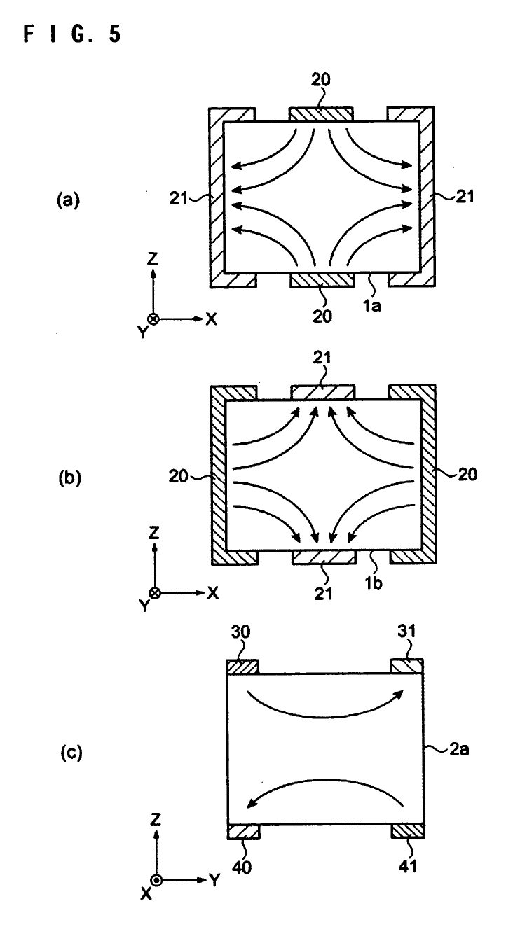

FIGS. 5(a) to 5(c) show patterns of the electrical field within the piezo electrode material. FIG. 5(a) is a cross section of the dotted line A-A shown in FIG. 2 in the driving mode and FIG. 5(b) is a cross section of the dotted line B-B shown in FIG. 2 in the driving mode. Further, FIG. 5(c) is a cross section of the dotted line C-C and D-D shown in FIG. 2 in the detecting mode.

In the driving mode of the resonator element 10, the arms 1a and 1b perform flexural vibration within the XY plane as shown in FIG. 4(a). Electrode structure of the arm 1a includes a first exciting electrode 20 formed in the center of the XY plane of the arm 1a and the second exciting electrode 21 formed from the end of the XY plane to the YZ plane of the arm 1a. Further, the first exciting electrode 20 and the second electrode 21 are located on the other arm 1b. The polarity of the exciting electrode in the arm 1b is reversed against that of the arm 1a for reversed phase of the flexural vibration. Namely, as shown in FIGS. 5(a) and 5(b), when positive voltage is applied to the first exciting electrode 20 and negative voltage is applied to the second exciting electrode 21, the electric field is generated with a direction from the first electrode 20 to the second electrode 21. Accordingly, the direction of the electric field on the right half side is reversed against that of left half side if the center of the arms 1a and 1b divides into a half of them. This direction of the electric field generates a stress for stretch on one hand and a stress for shrink on the other hand, bending the arms 1a and 1b. Hence, applying alternating voltage to the exciting electrodes 20 and 21, leads the arms 1a and 1b to perform flexural vibration.

Namely, the arms 1a and 1b have exciting electrodes for moving in a reversed phase with each other, making the arms 1a and 1b come on and off, and performing flexural vibration.

Next, the detecting mode of the resonator element is explained. During the flexural vibration of the resonator element 20 in the driving mode, it rotates along with Y-axis as the rotational axis the one Corioli force F and the other Corioli force F shown as the dotted line are alternatively excited toward the Z-axis as the line shown in FIG. 4(b) in the arms 1a and 1b. Then, a shearing stress is generated by the twist of the beam 2 due to the above Corioli forces excited by the arms 1a and 1b.

As shown n FIG. 5(c), a pair of first and second detecting electrodes 30 and 31 is located on the XY plane in the detecting part of a beam 2a of the beam 2 and a pair of third and fourth detecting electrodes 40 and 41 is located on the back side of the XY plane.

When the detecting part of a beam 2a twists, the same electrical field is generated at the cross section of the line C-C and the line D-D in FIG. 2. The generated pattern of the electrical field shows the direction from the first detecting electrode 30 to the second detecting electrode 31 and the direction from the third detecting electrode 41 to the fourth detecting electrode 40.

Then, the stress generated on the back and front surface of the detecting part of a beam 2a is converted into electrical voltage, outputting from the detecting electrodes 30, 31, 40 and 41 and it is differentially amplified and processed by an arithmetic circuit. Finally, this operation results in the determination of the direction and size of the rotational speed.

Here the detecting electrode is installed in the detecting part of a beam 2a in the first exemplary embodiment. But, the detecting electrode may be installed in either the detecting part of a beam 2b or 2c since a stress is generated in these parts 2b and 2c, being capable of detecting a stress of the beam 2 and detecting rotational speed.

Next, detecting acceleration of the Z-direction with respect to Y-axis rotation of the resonator element 10, which is disturbance against detecting a rotational speed, will be explained.

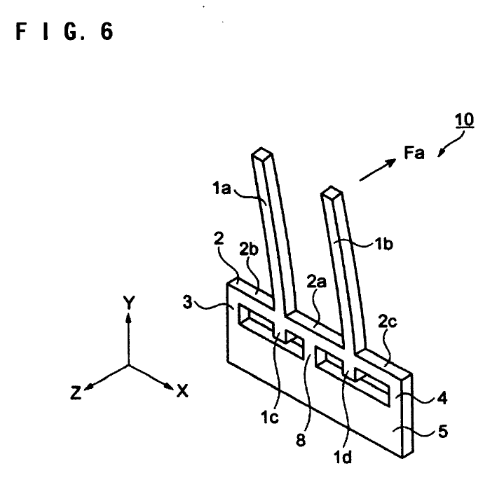

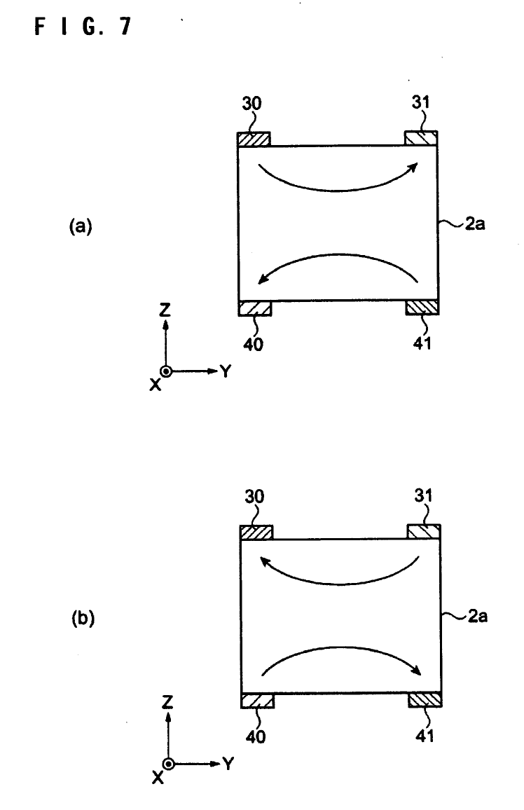

FIG. 6 is a perspective view of a state when the acceleration toward the Z-direction is applied to the resonator element. FIGS. 7(a) and 7(b) show a pattern of the electrical field within a piezo-electric material when the acceleration toward the Z-direction is applied to the resonator element. FIG. 7(a) is a cross sectional view of the line C-C shown in FIG. 2 and FIG. 7(b) is a cross sectional view of the line D-D shown in FIG. 2.

When the acceleration Fa toward the Z-direction is applied to the resonator element 10, the beam 2 is twisted since the arms 1a and 1b are deformed with the same phase toward the Z-direction as shown in FIG. 6. Here, in the cross section along the line C-C of the detecting part of a beam 2a in FIG. 2, an electrical field is generated with a direction from the first detecting electrode 30 to second detecting electrode 31 and a direction from the fourth detecting electrode 41 to third detecting electrode 40. Here, in the cross section along the line D-D of the detecting part of a beam 2a in FIG. 2, the electrical field is generated with a direction from the second detecting electrode 31 to the first detecting electrode 30 and a direction from the third detecting electrode 40 to the fourth detecting electrode 41.

Thus, the pattern of the electrical field generated in the detecting part of the beam 2a is different from that in the detecting mode for detecting the rotational speed, recognizing the mode of acceleration and making the differentiation of it from the rotational speed possible.

Therefore, in the resonator element 10 of the first exemplary embodiment, the detecting electrodes 30, 31, 40 and 41 are not spilt toward the direction of the thickness formed in the XY plane, easily attaining the detecting electrodes 30, 31, 40 and 41 with high precision. Further, the acceleration toward the Z-axis regarding Y-axis rotation of the resonator element 10, which is disturbance against detecting the rotational speed, can be detected, being capable of separating the rotational speed and the acceleration. Hence, the resonator element 10 is advantageous in product efficiency and sensitivity in detecting the rotational speed.

### Exemplary Modification 1

A modification of the location of the detecting electrode is explained hereafter.

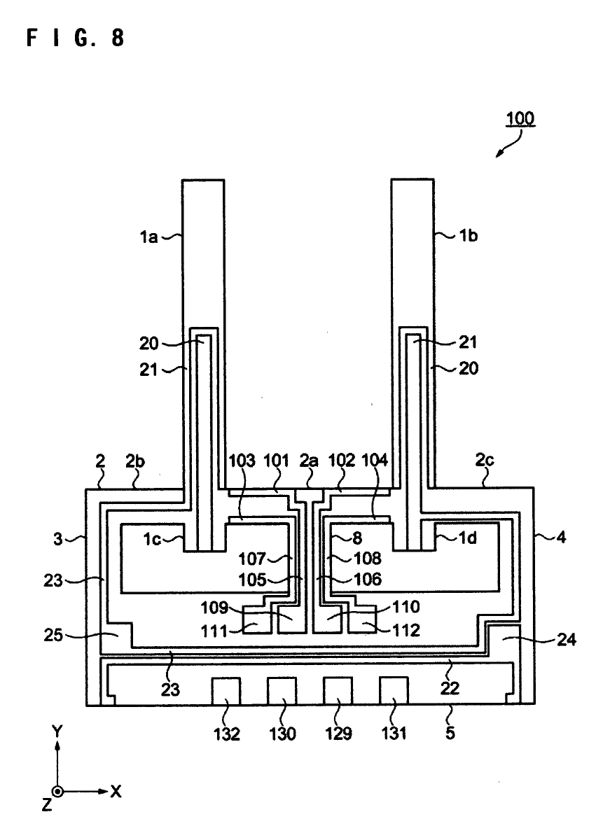

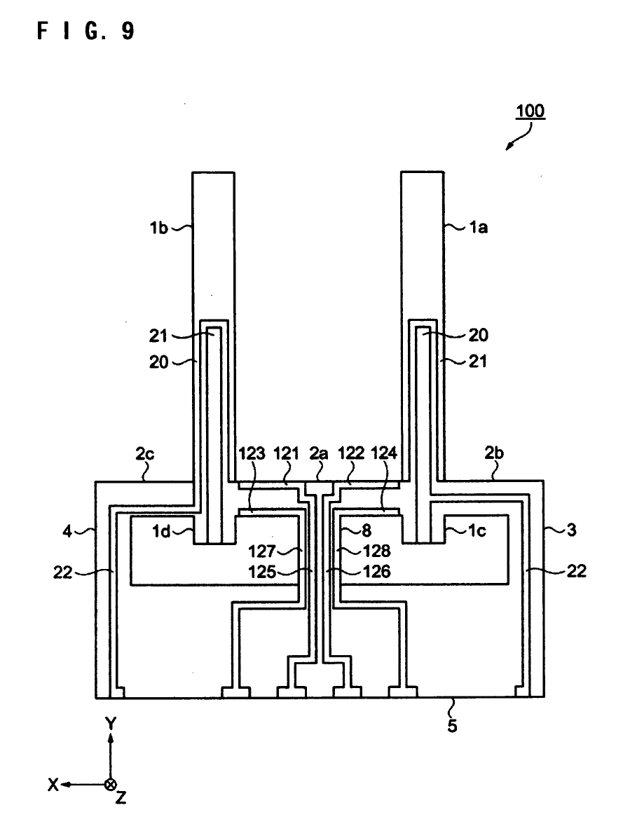

FIG. 8 is a plan view of the location of the electrode on one surface (a front surface) of the resonator element. FIG. 9 is a plan view of the location of the electrode on the other surface (a back surface) of the resonator element. The outer configuration of the resonator element, an exciting electrode, and these operations are the same as described above. As such, the same reference numerals are applied and their duplicate explanation is omitted.

Two pairs of detecting electrodes are installed in the XY plane on the front surface in the resonator element 100. One pair of detecting electrodes in the XY plane on the front surface includes the detecting electrodes 101 and 103 and the other pair of detecting electrodes includes the detecting electrodes 102 and 104. The detecting electrodes 101 and 103 are coupled to the lead electrodes 105 and 107, respectively, extend through the third connecting part 8 and are coupled to the detecting electrode pads 109 and 111 formed on the base 5. Similarly, the detecting electrodes 102 and 104 are coupled to the lead electrodes 106 and 108, respectively, extend through the third connecting part 8, and coupled to the detecting electrode pads 110 and 112 formed on the base 5.

Two pairs of detecting electrodes are installed in the XY plane of the detecting part of a beam 2a on the back surface in the resonator element 100, as described above. One pair of detecting electrodes in the XY plane includes the detecting electrodes 121 and 123 and the other pair of detecting electrodes includes the detecting electrodes 122 and 124. The detecting electrodes 121 and 123 are coupled to the lead electrodes 125 and 127, respectively, extend through the third connecting part 8 and are coupled to the detecting electrode pads 129 and 131 formed on the base 5 via the XZ plane from the end of the base 5.

The detecting electrodes 122 and 124 are coupled to the lead electrodes 126 and 128 respectively, extend through the third connecting part 8 and are coupled to the detecting electrode pads 130 and 132 formed on the base 5 via the XZ plane from the end of the base 5.

Accordingly, two pairs of detecting electrodes are installed on both the back and front surfaces of the detecting part of a beam 2a, leveling off detecting error caused by dimensional error of the electrodes and the configuration of the of the detecting part of a beam 2a and detecting the stress of the detecting part of a beam 2a with further high precision. Hence, it can detect the rotational speed with further high precision.

### Exemplary Modification 2

Next, a second modification 2 modifying the configuration of the resonator element 10 is explained.

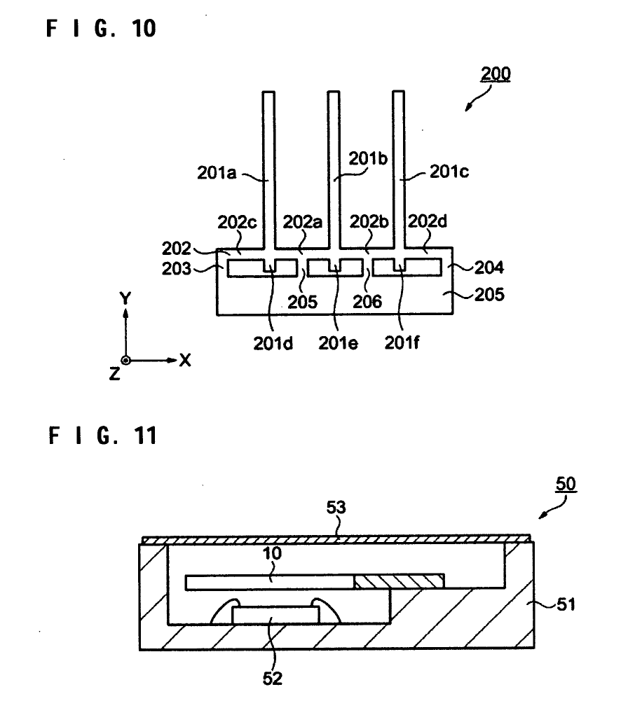

FIG. 10 is a plan view of the resonator element 10 having three arms. The resonator element 200 includes three rod-like arms 201a, 201b and 201c, with a predetermined length, which extend along with the Y-axis direction. Then, the arms are coupled to the rod-like beam 202 which extends in a direction (X-axis direction) perpendicular to the direction in which arms 201a, 201b and 201c extend. Further, the ends of three arms 201a, 201b and 201c, protrude from the beam 202, forming end portions of arms 201d, 201e and 201f.

The beam 202 includes a detecting part of a beam 202a located between the arms 201 and 201b, the detecting part of a beam 202b, located between the arms 201b and 201c, connects parts of a beam 202c and 202d, located outside of the arms 201a and 201c.

A first connecting portion 203 is coupled to the end of the connecting part of a beam 202c in the beam 202 and a second connecting portion 204 is coupled to the end of the connecting part of a beam 202d. The center portions of detecting parts of a beam 202a and 202b of the beam 202 are coupled to the third connecting portion 205 and the fourth connecting portion 206. The first connecting portion 203, the second connecting portion 204, the third connecting portion 205, and the fourth connecting portion 206 are coupled to the base 205. Further, each of the parts of resonator element 200 has the same uniform thickness toward the Z-direction (thickness direction).

The exciting electrodes (not shown) as described above are installed in the arms 201a, 201b and 201c, making each of arms perform flexural oscillation with reverse phase each other along the X-axis in the driving mode.

Further, the detecting electrodes (not shown) as described above are installed in the detecting parts of a beam 202a and 202b. In the detecting mode with respect to Y-axis rotation, each of arms perform flexural oscillation with reverse phase each other along the Z-axis. Hence, a stress is generated in the detecting parts of a beam 202a and 202b, recognizing the size and direction of the rotational speed by detecting the stress with a detecting electrode.

### Second Exemplary Embodiment

FIG. 11 is a cross section of the resonator of the second exemplary embodiment.

The resonator 50 includes a resonator element 10, a circuit element 52, a container 51 and a lid 53. The container 51 made of ceramic has the concave portion of which a part is opened. The resonator element 10 is attached to the concave portion with adhesive, electrically connecting the resonator element 10 to a wiring formed and stickled in the container 51. In the bottom of the concave portion of the container 51, a exciting circuit for exciting the resonator element 10 and a circuit element 52 for computing and outputting the rotational speed signal based on the detected stress are installed. The circuit element 52 is coupled to a wiring formed in the container by wire bonding. The lid 53 covers the front surface of the container 51, making the inside of the resonator encapsulated with vacuum atmosphere.

Hence, the resonator 50 is provided with the resonator element 10 described above, showing high production efficiency and high sensitivity of detecting the rotational speed.

### Third Exemplary Embodiment

Next, electronic equipment in the third exemplary embodiment is explained.

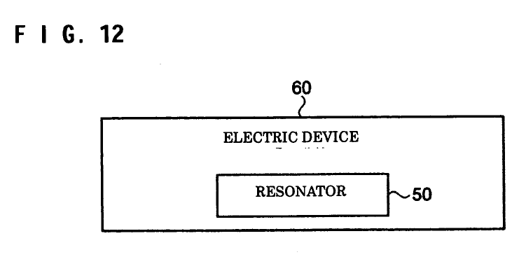

FIG. 12 illustrates a structure of an electronic device. An electronic device 60 includes a resonator 50 having the resonator element described above.

The electronic device 60 using the resonator, may be a mobile phone, a digital camera, or a navigation system. In these devices, it is necessary to detect the change of a position.

In these devices, the characteristics and specification of the above-mentioned electronic element have excellent sensitivity for detecting a rotational speed.

What is claimed is:

1. A resonator element made of piezo-electric material having a thickness in a Z-direction, the resonator element comprising:
a plurality of rod-like arms extending in a Y-direction, which is a rotational axis for a rotation of the resonator element;
a plurality of rod-like beams extending in an X-direction, perpendicular to the direction in which the plurality of rod-like arms extend, and connecting to the arms in an XY-plane;
an exciting electrode, located on a plane that opposes the XY-plane and opposes a YZ-plane of the plurality of rod-like arms, to excite the plurality of rod-like arms to perform a curvature movement on the XY-plane; and
a detecting electrode, located on a plane that opposes the XY-plane of the beam, to detect a stress of the beam, which is generated by a Coriolis force yielded in the plurality of rod-like arms by the rotation of the resonator element corresponding to the Y-axis, as the rotational axis.

2. The resonator element according claim 1, the piezo-electric material being quartz.

3. The resonator element according claim 1, the piezo-electric material being gallium phosphate (Ga PO₄).

4. The resonator element according claim 1, at least a pair of detecting electrodes being installed on one surface of the XY-plane of the beam, and at least a pair of detecting electrodes being installed on another surface of the XY-plane of the beam.

5. The resonator element according claim 1, the detecting electrode being located between two of the plurality of rod-like arms of the beam.

6. The resonator element according claim 1, a configuration of the resonator element, the exciting electrode and the detecting electrode being formed by a photolithography.

7. A resonator, comprising:
the resonator element according to the claim 1.

8. An electronic device, comprising:
the resonator according to claim 7.
